(19) United States
(12) Patent Application Publication
(10) Pub. No.: US 2025/0372560 A1
(43) Pub. Date: Dec. 4, 2025

(54) SEMICONDUCTOR DIE, SEMICONDUCTOR PACKAGE AND METHOD FOR MANUFACTURING SEMICONDUCTOR DIE

(71) Applicant: Taiwan Semiconductor Manufacturing Company, Ltd., Hsinchu (TW)

(72) Inventors: Wei-Ting Chen, Tainan City (TW); Tzu-Chun Tang, Kaohsiung City (TW); Chung-Hao Tsai, Changhua County (TW); Chen-Hua Yu, Hsinchu City (TW)

(73) Assignee: Taiwan Semiconductor Manufacturing Company, Ltd., Hsinchu (TW)

(21) Appl. No.: 18/731,356

(22) Filed: Jun. 3, 2024

(51) Int. Cl. H01L 23/00; H01L 25/065

(52) U.S. Cl. CPC H01L 24/20; H01L 24/05; H01L 24/08; H01L 25/0657; H01L 2224/05569; H01L 2224/0557; H01L 2224/08146; H01L 2224/2101; H01L 2225/06544; H01L 2924/30101

(57) ABSTRACT

A semiconductor die, a semiconductor package and a method for manufacturing the semiconductor die are provided. The semiconductor die includes: active devices, formed on a front surface of a substrate; frontside metallization layers, stacked over the active devices; bond pads, laid over the frontside metallization layers, and arranged along a frontside of the semiconductor die; backside metallization layers, formed on a back surface of the substrate; backside pads, formed on the backside metallization layers, and arranged along a backside of the semiconductor die; and through device vias, continuously extending through the backside metallization layers and the substrate from the backside pads, and further extending into the frontside metallization layers.

### BACKGROUND

In general, an integrated circuit includes interconnected electronic components formed on a front side of a semiconductor substrate. Along with rapid growth of semiconductor industry, integration density of the electronic components has been significantly increased. Inevitably, length and number of the interconnections for interconnecting the electronic components are increased as well. In other words, conduction features for interconnecting and powering the electronic components become crowder at the front side of the semiconductor substrate. A solution for releasing valuable frontside interconnection area is moving a portion of the conduction features from the front side of the semiconductor substrate to a back side of the semiconductor substrate, and efficient conduction paths for bridging the front side and the back side of the semiconductor substrate are required.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic cross-sectional view illustrating a semiconductor die, according to some embodiments of the present disclosure.

FIG. 1B is an enlarged cross-sectional view schematically illustrating a TDV in the semiconductor die shown in FIG. 1A, according to some embodiments of the present disclosure.

FIG. 1C is an enlarged plan view schematically illustrating the TDV shown in FIG. 1B, according to some embodiments of the present disclosure.

FIG. 2 is a flow diagram illustrating a process for forming the semiconductor die shown in FIG. 1A, according to some embodiments of the present disclosure.

FIG. 3A through FIG. 3F are schematic cross-sectional views illustrating intermediate structures at various stages during the process illustrated in FIG. 2.

FIG. 4A is an enlarged cross-sectional view schematically illustrating a TDV penetrating through a substrate reformed by an insulating material, according to some embodiments of the present disclosure.

FIG. 4B is a schematic plan view of the TDV shown in FIG. 4A.

FIG. 5 is a schematic cross-sectional view illustrating a semiconductor die, according to some embodiments of the present disclosure.

FIG. 6A is a schematic cross-sectional view illustrating a semiconductor package, according to some embodiments of the present disclosure.

FIG. 6B is a schematic cross-sectional view illustrating a semiconductor package, according to some embodiments of the present disclosure.

FIG. 7A is a schematic cross-sectional view illustrating a semiconductor package, according to some embodiments of the present disclosure.

FIG. 7B is a schematic cross-sectional view illustrating a semiconductor package, according to some embodiments of the present disclosure.

FIG. 8A is a schematic cross-sectional view illustrating a semiconductor package, according to some embodiments of the present disclosure.

FIG. 8B is a schematic cross-sectional view illustrating a semiconductor package, according to some embodiments of the present disclosure.

FIG. 9A is a schematic cross-sectional view illustrating a semiconductor package, according to some embodiments of the present disclosure.

FIG. 9B is a schematic cross-sectional view illustrating a semiconductor package, according to some embodiments of the present disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides a solution for efficiently bridging front side and back side of a semiconductor die, and the semiconductor die can be bonded with one or more of other package component(s) in a semiconductor package.

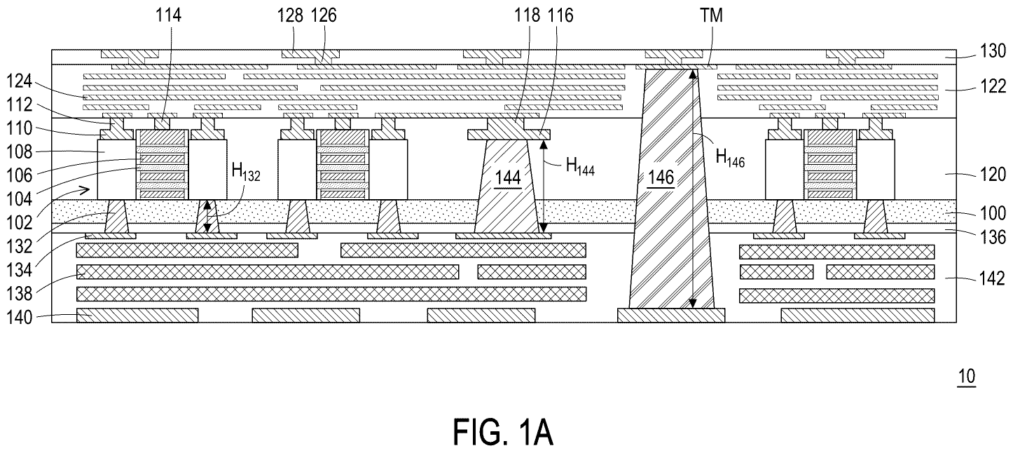

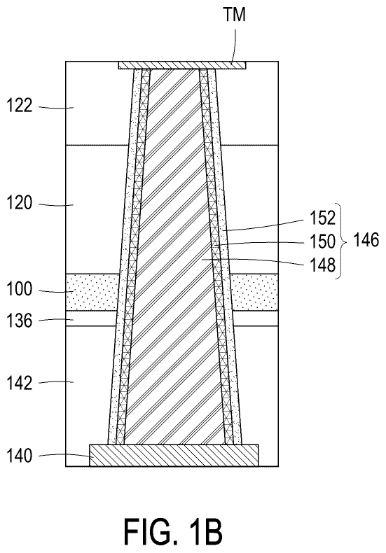

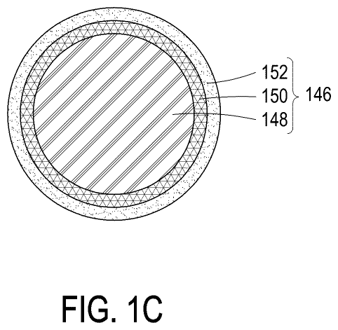

FIG. 1A is a schematic cross-sectional view illustrating a semiconductor die 10, according to some embodiments of the present disclosure.

The semiconductor die 10 includes interconnected active devices built on a substrate 100. According to some embodiments, the substrate 100 includes a semiconductor layer as a base layer of the active devices. As will be further described, in other embodiments, the semiconductor layer is replaced by an insulating layer after formation of the active devices. For illustration purpose, a surface of the substrate 100 on which the active devices are formed is referred to as a front surface of the substrate 100. Correspondingly, the substrate 100 has a back surface facing away from the front surface.

The active devices may include field effect transistors (FETs) 102 (or, in short, transistors 102). Without changing essential operation principle of the transistors 102, the transistors 102 can have various forms. As an example shown in FIG. 1A, the transistors 102 may be formed as gate-all-around FETs (GAAFETs). More specifically, the transistors 102 may respectively include a stack of channel structures 104 formed on the substrate 100 and vertically separated from one another; a gate structure 106 wrapping all around the channel structures 104; and source/drain structures 108 in lateral contact with the channel structures 104.

Although not shown, the transistors 102 may be alternatively formed as fin-type FETs (FinFETs). Each FinFET may include one or more channel structure(s) formed in fin shape; a gate structure in contact with top and lateral surfaces of the channel structure(s); and source/drain structures in lateral contact with the channel structure(s). According to an earlier technology node, the transistors 102 may be formed as planar type FETs, which respectively use a shallow region of the substrate 100 as a channel region, and include a gate structure in contact with the channel region from above. Optionally, each planar type FET may further include source/drain structures formed into the channel region at opposite sides of the gate structure. As described, structural features of the transistors 102 are dependent on the generation of manufacturing process, the present disclosure is not limited thereto.

To out-rout source/drain terminals of the transistors 102, contact patterns 110 and contact vias 112 may be formed on the source/drain structures (e.g., the source/drain structures 108) of the transistors 102. Similarly, contact vias 114 may be formed on the gate structures (e.g., the gate structures 106) of the transistors 102, for coupling control signals to gate terminals of the transistors 102. The contact patterns 110 provide lateral conduction paths, and may be formed as line patterns and/or pad patterns. On the other hand, the contact vias 112, 114 provide vertical conduction paths, and may be formed as pillars (with or without tapering feature).

In addition to local transistor contacts including the contact patterns 110 and the contact vias 112, 114, middle-end-of-line (MEOL) metallization patterns may further include contact pads 116 providing landing for through substrate vias (TSVs) as will be described in greater details, and also include contact vias 118 standing on the contact pads 116. As the through substrate vias are disposed around the transistors 102, the contact pads 116 and the contact vias 118 overlapping the through substrate vias may be laterally spaced apart from the contact patterns 110 and the contact vias 112, 114 laid on the transistors 102.

The transistors 102 as well as the MEOL metallization patterns (e.g., including the contact patterns 110, the contact vias 112, 114, 118 and the contact pads 116) are embedded in at least one layer of interlayer dielectric (ILD) 120, such as two or more layers of the ILDs 120 stacked on the substrate 100. Although not shown, an etching stop layer may lie below the bottommost one of the ILD 120.

As a frontside back-end-of-line (BEOL) structure, multiple metallization layers are stacked on the MEOL metallization patterns and the ILDs 120. The metallization layers include a stack of dielectric layers 122 as well as conductive patterns 124 and conductive vias (not shown) embedded in the dielectric layers 122. As similar to the contact patterns 110, the conductive patterns 124 provide lateral conduction paths, and may be formed as line patterns and/or pad patterns. The topmost ones of the conductive patterns 124 may also be referred to as top metals TM, and some of the top metals TM may be served as landing pads for through device vias (TDVs), as will be described in greater details. On the other hand, as similar to the contact vias 112, 114, 118, the conductive vias (not shown) provide vertical conduction paths, and may be formed as pillars (with or without tapering feature).

On top of the frontside BEOL structure, bonding features are disposed for coupling the top metals TM to external signal sources. The bonding features may include bond vias 126 standing on the top metals TM, and may further include bond pads 128 lying on the bond vias 126. According to some embodiments, the bond pads 128 are configured to engage with an external component (e.g., another semiconductor die, a semiconductor package or a package substrate). In alternative embodiments, the bond pads 128 are designed to be in contact with an external component through electrical connectors (e.g., solder bumps or the like). In either case, the bond vias 126 and the bond pads 128 may be embedded in one or more insulating layers 130. In some embodiments, the insulating layer 130 surrounding the bond pads 128 may have a top surface substantially coplanar with top surfaces of the bond pads 128. The top surfaces of the insulating layer 130 and the bond pads 128 may define a frontside of the semiconductor die 10.

As described, the transistors 102 formed on the front surface of the substrate 100 are routed to the frontside of the semiconductor die 10 through the MEOL metallization patterns and conductive features in the frontside BEOL structure. Moreover, the transistors 102 can be routed and powered through conductive features formed from the back surface of the substrate 100.

Specifically, backside vias 132 may extend into the substrate 100 from the back surface of the substrate 100, and penetrate through the substrate 100 to establish contact with the source/drain structures (e.g., the source/drain structures 108) of the transistors 102 formed on the front surface of the substrate 100. In this way, the source/drain structures (e.g., the source/drain structures 108) of the transistors 102 can be connected to one or more layers of backside interconnects 134 formed on the back surface of the substrate 100. In some embodiments, the back surface of the substrate 100 is lined with an insulating layer 136. In these embodiments, the backside interconnects 134 can be separated from the substrate 100 through the insulating layer 136, and the backside vias 132 may penetrate through the insulating layer 136 as well.

In addition to be routed through the backside vias 132 and the backside interconnects 134, the transistors 102 may be powered by layers of backside power rails 138 stacked over the back surface of the substrate 100. The power rails 138 may be configured to carry a power supply voltage and a reference voltage (e.g., a ground voltage), and may be connected to the transistors 102 through the backside interconnects 134 and the backside vias 132. To couple the power rails 138 to the power supply voltage and the reference voltage, the power rails 138 may be connected to backside pads 140 disposed along a backside of the semiconductor die 10. Further, the backside interconnects 134, the backside power rails 138 and the backside pads 140 may be embedded in a stack of backside dielectric layers 142. A bottom surface of the bottommost backside dielectric layer 142 and bottom surfaces of the backside pads 140 may collectively define the backside of the semiconductor die 10.

According to some embodiments, some of the backside interconnects 134 are connected to the conductive patterns 124 in the frontside BEOL structure along through substrate vias (TSVs) 144. As similar to the backside vias 132, the TSVs 144 extend from the corresponding backside interconnects 134, and penetrate through the substrate 100. In those embodiments where the back surface of the substrate 100 is lined with the insulating layer 136, the TSVs 144 penetrate through the insulating layer 136 as well. As a difference from the backside vias 132, the TSVs 144 are connected to the conductive patterns 124 in the frontside BEOL structure without the transistors 102 in between.

A height of the TSVs 144 may vary, in accordance with process adopted for forming the TSVs 144. As an example shown in FIG. 1A, when a TSV-middle process is adopted for forming the TSVs 144, the TSVs 144 may extend through the substrate 100 and the dielectric layer(s) 120, to land on the contact pads 116 in the MEOL metallization patterns. In this way, some of the backside interconnects 134 are routed to the conductive patterns 124 in the frontside BEOL structure through the TSVs 144, the contact pads 116 and the contact vias 118. It should be appreciated that, other TSV formation processes can be adopted, and related structures may be modified accordingly. For instance, when using a TSV-first process, the resulted TSVs may be terminated at the front surface of the substrate 100, and may be connected to the contact pads 116 through additional contact plugs. As another example, when a TSV-last process is adopted, the resulted TSVs may directly extend to the conductive patterns 124 in the BEOL structure (e.g., to some of the top metals TM), and the contact pads 116 as well as the contact vias 118 may be omitted from the MEOL metallization patterns.

In addition to the backside vias 132 and the TSVs 144, through device vias (TDVs) 146 provide additional conduction paths for bridging the frontside and the backside of the semiconductor die 10. As similar to the backside vias 132 and the TSVs 144, the TDVs 146 penetrate through the substrate 100. In those embodiments where the back surface of the substrate 100 is lined with the insulating layer 136, the TDVs 146 extend through the insulating layer 136 as well. As a difference from the backside vias 132 and the TSVs 144, the TDVs 146 extend through (but isolate from) the backside interconnects 134 and the backside power rails 138, to reach some of the backside pads 140. More specifically, the TDVs 146 extend through the backside dielectric layers 142 embedded with the backside interconnects 134 and the backside power rails 138, and are respectively bounded at a top surface of one of the backside pads 140 by one end. According to some embodiments, the TDV 146 extend to reach some of the top metals TM at top of the frontside BEOL structure by the other end. In these embodiments, the TDVs 146 extend aside the transistors 102 and the MEOL metallization patterns (e.g., including the contact pads 116 and the contact vias 118), and may extend into the frontside BEOL structure. To be more specific, the TDVs 146 extend through the ILD(s) 120 surrounding the transistors 102 and the MEOL metallization patterns, and further extend through the dielectric layers 122 embedded with the conductive patterns 124 lying below the top metals TM.

In this way, direct electrical connection between the backside pads 140 at the backside of the semiconductor die 10 and the top metals TM near the frontside of the semiconductor die 10 can be established by the TDVs 146. Without disposing the TDVs 146, the backside pads 140 and the top metals TM may be otherwise connected through a combination of additional conductive patterns and vias arranged through the backside power rails 138 and the backside interconnects 134, additional TSVs through the substrate 100, additional MEOL metallization patterns and additional conductive patterns and vias further formed in the frontside BEOL structure, and a much greater voltage drop may be resulted along the paths from the backside pads 140 to the top metals TM, owing to high interfacial resistance at many interfaces along the paths. That is, IR loss between the backside pads 140 and the top metals TM can be significantly reduced by employing the interface-less TDVs 146. In some embodiments where the semiconductor die 10 is attached to another package component by its frontside, signals provided from the backside of the semiconductor die 10 can be efficiently transferred to the frontside of the semiconductor die 10 through the TDVs 146.

The TDVs 146 are greater in height as compared to the backside vias 132 and the TSVs 144. The backside vias 132 extending from the backside interconnects 134 to the front surface of the substrate 100 may have a height H₁₃₂ substantially equal to or greater than a thickness of the substrate 100. As the TSVs 144 may further protrude from the front surface of the substrate 100, a height H₁₄₄ of the TSVs 144 may be greater than the height H₁₃₂ of the backside vias 132. Further, as the TDVs 146 protrude from both sides of the substrate 100 and extend to the backside pads 140 and the top metals TM at top of the frontside BEOL structure by opposite ends, a height H₁₄₆ of the TDVs 146 is greater than the height H₁₄₄ of the TSVs 144 and the height H₁₃₂ of the backside vias 132.

In those embodiments where the back surface of the substrate 100 is lined with the insulating layer 136, the height H₁₃₂ of the backside vias 132 may be substantially equal to or greater than a total thickness of the substrate 100 and the insulating layer 136. In those embodiments where the TSVs 144 are landed on the contact pads 116 in the MEOL metallization patterns, a difference between the heights H₁₄₄, H₁₃₂ may be close to a height of the front-end-of-line (FEOL) structure including the transistors 102. In addition, a difference between the height H₁₄₆ of the TDVs 146 and the height H₁₄₄ of the TSVs 144 may include the depth by which the TDVs 146 protrude into the frontside BEOL structure and the distance by which the TDVs 146 penetrate through the backside power rails 138. It should be appreciated that, a greater difference between the heights H₁₄₄, H₁₃₂ and yet a smaller difference between the heights H₁₄₄, H₁₄₆ may be resulted when the TSVs 144 further protrude into the frontside BEOL structure. On the other hand, a smaller difference or no difference between the heights H₁₄₄, H₁₃₂ and yet a greater difference between the heights H₁₄₄, H₁₄₆ may be resulted when the TSVs 144 do not protrude from the front surface of the substrate 100 at all.

Since the backside vias 132 and the TSVs 144 are formed from the backside of the substrate 100, the backside vias 132 and the TSVs 144 may taper away from the backside of the substrate 100. Similarly, the TDVs 146 may taper along the same direction. In those embodiments where the TDVs 146 extend from the backside pads 140 to the top metals TM in the frontside BEOL structure, the TDVs 146 may taper away from the backside pads 140, to the top metals TM. Further, as will be described in greater details, a non-Bosch etching process is used for forming the TDVs 146 in some embodiments, and sloped or vertical sidewalls of the resulted TDVs 146 may have substantially flat surfaces in a cross-sectional view, rather than rough surfaces with many lateral recesses.

FIG. 1B is an enlarged cross-sectional view schematically illustrating one of the TDVs 146 in the semiconductor die 10, according to some embodiments of the present disclosure. FIG. 1C is an enlarged plan view schematically illustrating the TDV 146, according to some embodiments of the present disclosure.

In these embodiments, each TDV 146 includes a conductive column 148, and further includes a barrier layer 150 as well as an insulating liner 152 laterally enclosing the conductive column 148. The conductive column 148 provides main conduction path for the TDV 146, and may be formed of copper or copper alloy. The barrier layer 150 is configured to prevent metal elements in the conductive column 148 from out-diffusing into surrounding components, and may be formed of TiN, TaN, W, the like or combinations thereof. In addition, the insulating liner 152 is functioned for ensuring that the TDV 146 can be electrically isolated from surrounding components (e.g., isolated from the substrate 100), and is formed of an insulating material, such as silicon oxide, silicon nitride, silicon oxynitride, silicon oxycarbide, the like or combinations thereof.

The insulating layer 150 may not cover bottom and top ends of the conductive column 148, to avoid from cutting off the electrical connection between the conductive column 148 and the top metal TM as well as the backside pad 140 at opposite sides. According to some embodiments, the barrier layer 150 may not cover the bottom and top ends of the conductive column as well. In alternative embodiments, the barrier layer 150 may further extend in between the conductive column 148 and the corresponding top metal TM, whereas the insulating liner 152 is only formed around the conductive column 148.

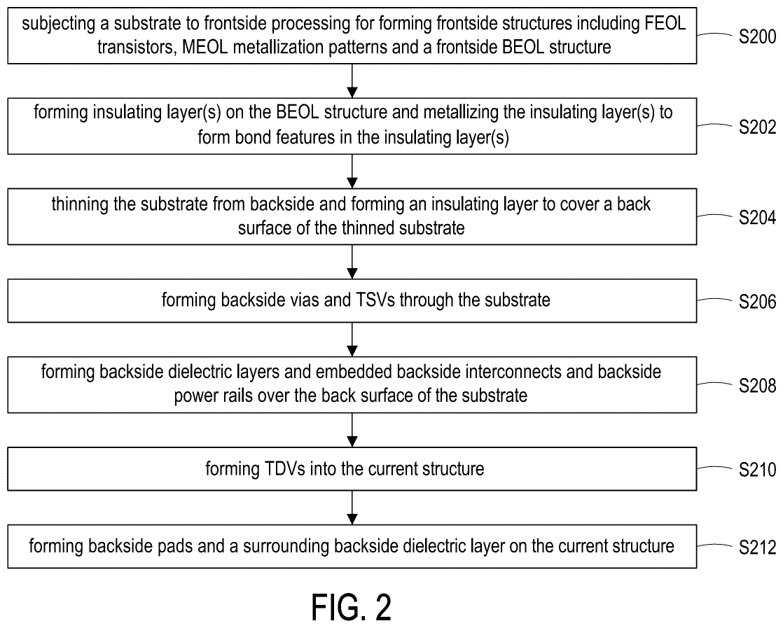

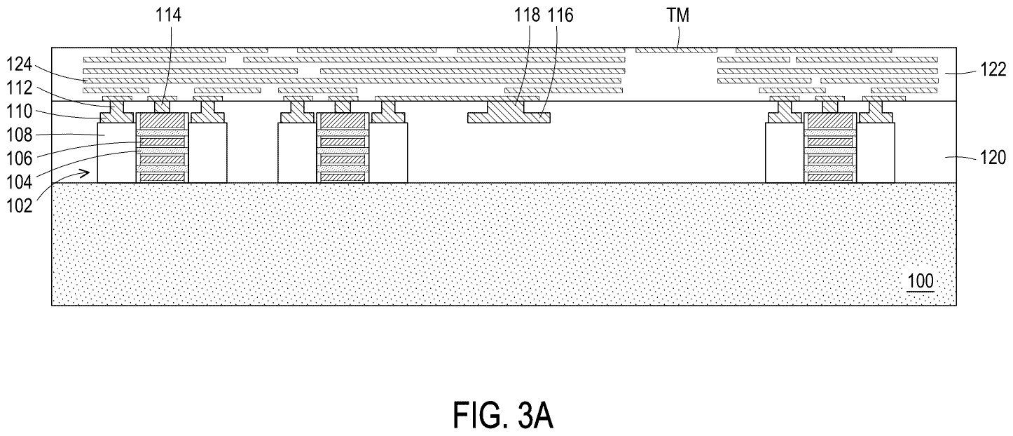

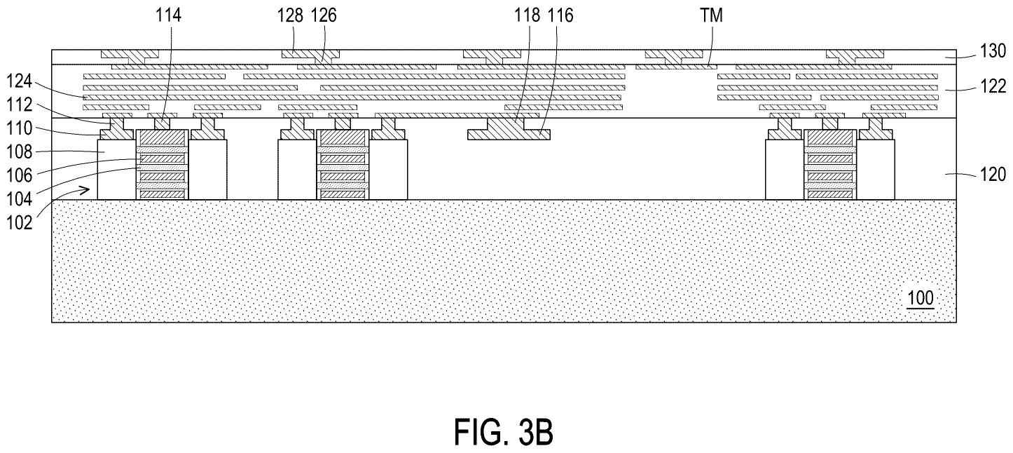

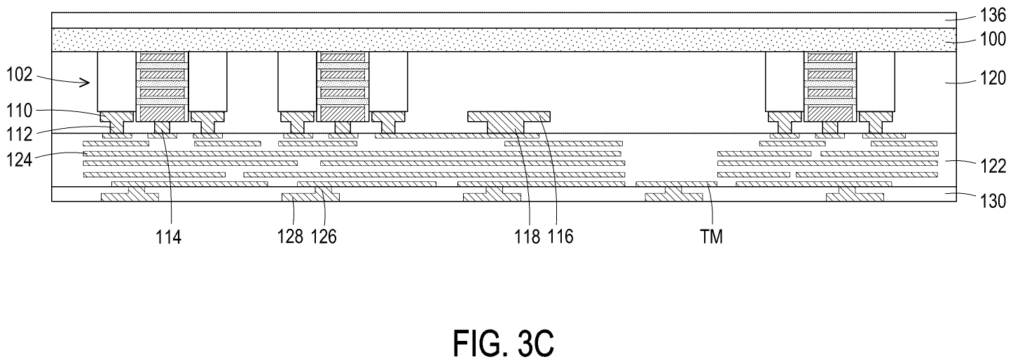

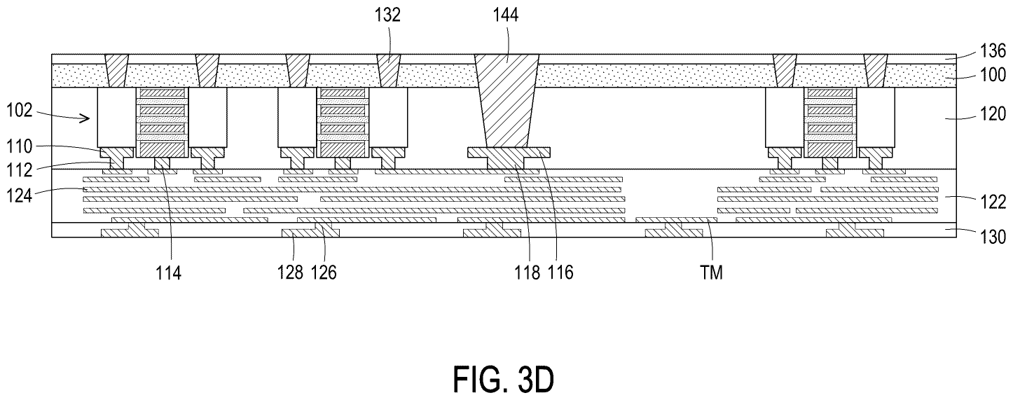

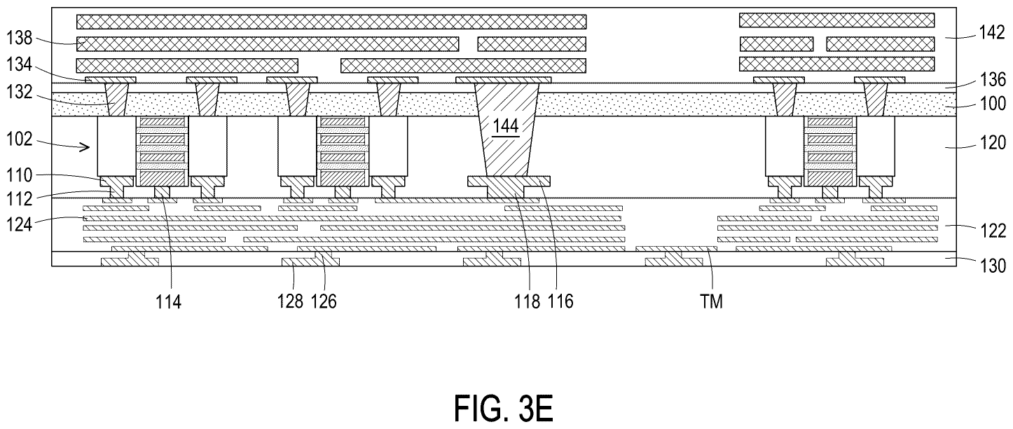

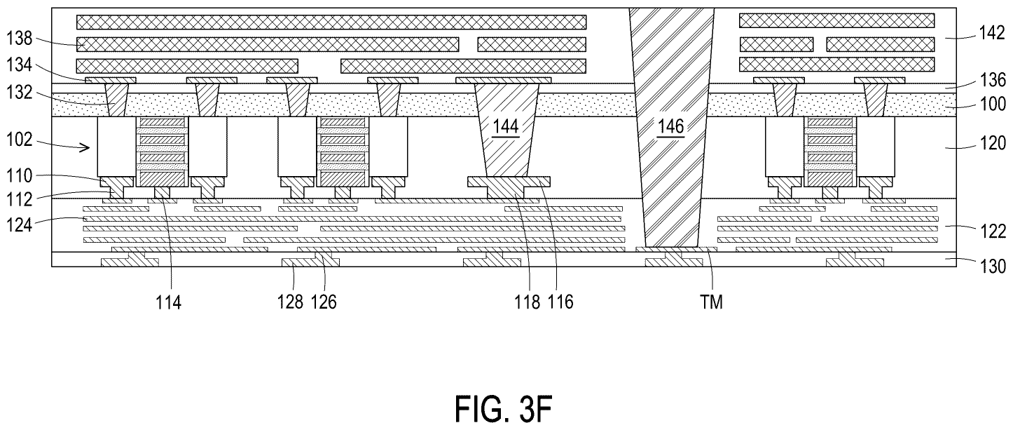

FIG. 2 is a flow diagram illustrating a process for forming the semiconductor die 10, according to some embodiments of the present disclosure. FIG. 3A through FIG. 3F are schematic cross-sectional views illustrating intermediate structures at various stages during the process illustrated in FIG. 2.

Referring to FIG. 2 and FIG. 3A, an operation S200 of subjecting the substrate 100 to frontside processing is performed at an initial stage of the process. Currently, the substrate 100 has not been thinned from backside, and is subjected to the frontside processing by its front surface. Specifically, the frontside processing may include formation of the transistors 102, the ILD(s) 120, the MEOL metallization patterns (e.g., including the contact patterns 110, the contact vias 112, 114, 118 and the contact pads 116) and the frontside BEOL structure (e.g., including the dielectric layers 122 and the conductive patterns 124 as well as the conductive vias (not shown) spreading in the dielectric layers 122). It should be appreciated that, those skilled in the art may adopt suitable processes for forming these components. Without departing from their operation principle and/or function, these components may vary in accordance to the selected manufacturing process.

Referring to FIG. 2 and FIG. 3B, at an operation S202, the insulating layer(s) 130 are deposited and metallized to form the bond vias 126 and the bond pads 128. As the bonding features including the bond vias 126 and the bond pads 128 are formed, the top metals TM in the frontside BEOL structure can be routed to the frontside of the semiconductor die 10 defined by the topmost insulating layer 130 and the bond pads 128.

Referring to FIG. 2 and FIG. 3C, at an operation S204, the substrate 100 is thinned and the insulating layer 136 is formed to cover the back surface of the thinned substrate 100. Initially, the structure shown in FIG. 3B may be flipped over, and the thinning process is performed on the exposed surface of the substrate 100. As an example, the thinning process may be implemented by a grinding process. After the thinning, the insulating layer 136 may be deposited to cover the exposed surface (i.e., the backs surface) of the thinned substrate 100.

Referring to FIG. 2 and FIG. 3D, at an operation S206, the backside vias 132 and the TSVs 144 are formed through the insulating layer 136 and the substrate 100. An etching process may be involved for forming openings to be filled with the backside vias 132 and the TSVs 144. The openings for the backside vias 132 may extend to the source/drain structures (e.g., the source/drain structures 108) of the transistors 102, whereas the openings for the TSVs 144 may extend to the contact pads 116. After formation of these openings, material(s) for forming the backside vias 132 and the TSVs 144 is/are filled into these openings. As a planarization process may be performed to remove excess portions of the material(s) outside the openings, portions of the material(s) in the openings may remain to form the backside vias 132 and the TSVs 144.

Referring to FIG. 2 and FIG. 3E, at an operation S208, some of the backside dielectric layers 142 are deposited and metallized to form the backside interconnects 134 and the backside power rails 138. As similar to formation of the frontside BEOL structure, a series of damascene processes may be used for forming the backside dielectric layers 142 and the backside interconnects 134 as well as the backside power rails 138 embedded in the backside dielectric layer 142.

Referring to FIG. 2 and FIG. 3F, at an operation S210, the TDVs 146 are formed into the current structure. Specifically, a non-Bosch etching process may be involved for forming openings to be filled with the TDVs 146. The openings extend through the deposited backside dielectric layers 142, the insulating layer 136, the substrate 100, the ILD(s) 120 and the dielectric layers 122, to reach some of the top metals TM in the frontside BEOL structure. Thereafter, an insulating liner as well as a barrier layer are conformally formed on the current structure. Subsequently, an etching process (e.g., an anisotropic etching process) may be used for removing portions of the insulating liner and the barrier layer that cover the topmost backside dielectric layer 142 and extend along the top metals TM overlapped with the openings. As a result, portions of the insulating liner and the barrier layer remain on sidewalls of the openings form the insulating liners 152 and the barrier layers 150 of the TDVs 146 (described with reference to FIG. 1B and FIG. 1C), respectively. Afterwards, a conductive material is filled into the openings. As a planarization process may be performed to remove excess portions of the conductive material outside the openings, portions of the conductive material in the openings may remain to form the conductive columns 148 of the TDVs 146 (described with reference to FIG. 1B and FIG. 1C).

As another alternative, the conformal barrier layer may not be subjected to patterning before providing the conductive material. Instead, the conformal barrier layer and the conductive material may be patterned at the same time by the planarization process. In this way, the resulted barrier layers 150 may extend in between the conductive materials 148 and the underlying top metals TM.

Thereafter, at an operation S212, the backside pads 140 and the surrounding backside dielectric layer 142 are formed on the current structure. As a singulation process is performed through the current wafer structure, the semiconductor die 10 as shown in FIG. 1A can be singulated from the wafer structure.

Although the operations of the manufacturing process for forming the semiconductor die 10 are illustrated as being performed in a certain order, these operations can be performed by any logical order. For example, according to some embodiments, the operation S202 of forming the insulating layer(s) 130 and the embedded bonding features as described with reference to FIG. 3B is performed after the operation S210 of forming the TDVs 146 as described with reference to FIG. 3F and the operation S212 of forming the backside pads 140 and the surrounding backside dielectric layer 142. In these embodiments, the wafer structure may be flipped again after forming the backside pads 140 and the surrounding backside dielectric layer 142, for forming the insulating layer(s) 130 and the embedded bonding features.

Moreover, in some embodiments, the substrate 100 is entirely removed during the operation S204 as described with reference to FIG. 3C, and an insulating material is provided to an expected thickness, for reforming the substrate 100. In these embodiments, the TDVs 146 may not include the insulating liners 152 for isolating the conductive columns 148 and the barrier layers 150 from the semiconductor material in the substrate 100.

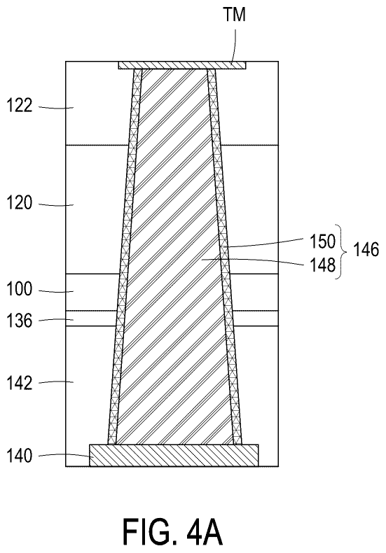

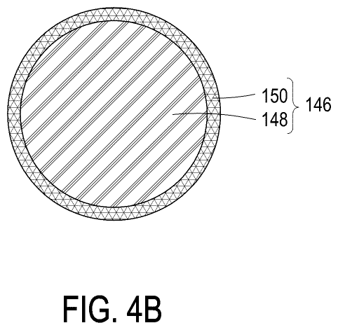

FIG. 4A is an enlarged cross-sectional view schematically illustrating a TDV 146 penetrating through the substrate 100 reformed by an insulating material, according to some embodiments of the present disclosure. FIG. 4B is a schematic plan view of the TDV 146 shown in FIG. 4A.

Referring to FIG. 4A and FIG. 4B, in these embodiments, the conductive column 148 and the barrier layer 150 in the TDV 146 may be in contact with surrounding components (e.g., including the reformed substrate 100) without an insulating liner in between. In regarding manufacturing, deposition and patterning of the insulating liner in the operation S210 described with reference to FIG. 3F may be omitted.

Further, more variations can be applied to the TDVs 146 and surrounding components, for further reducing IR loss along the paths between chip backside and chip frontside.

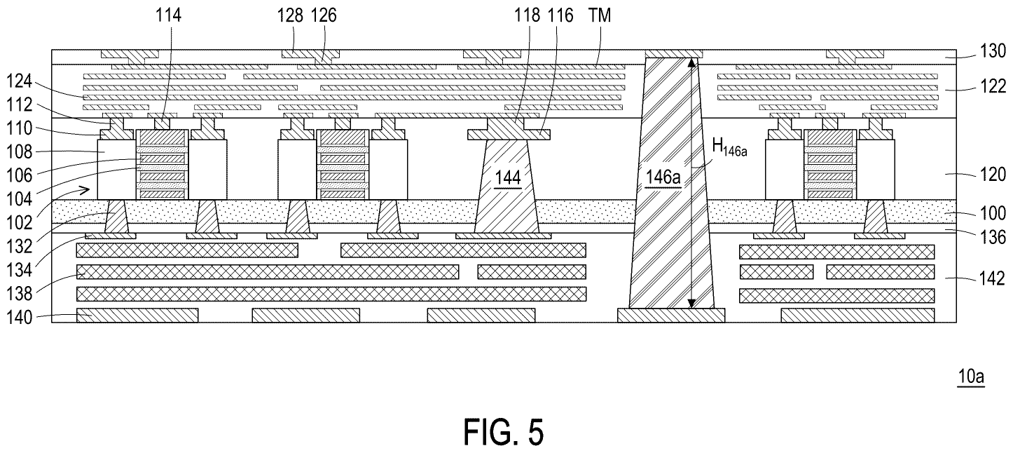

FIG. 5 is a schematic cross-sectional view illustrating a semiconductor die 10a, according to some embodiments of the present disclosure.

The semiconductor die 10a is substantially identical with the semiconductor die 10 described with reference to FIG. 1A through FIG. 1C, except for a few differences. Specifically, TDVs 146a in the semiconductor die 10a extend from the backside pads 140 at a backside of the semiconductor die 10a to the bond pads 128 at a frontside of the semiconductor die 10a. In this way, the TDVs 146a may be in direct contact with the bond pads 128, rather than being connected to the bond pads 128 through the top metals TM and the bond vias 126 in between. Accordingly, interfaces along the paths from the backside pads 140 to the bond pads 128 can be further reduced, such that IR loss along the paths can be further lowered. That is, signals provided to the backside pads 140 can be more efficiently transferred to the bond pads 128 at the frontside of the semiconductor die 10a.

In these embodiments, the TDVs 146a entirely penetrate through the frontside BEOL structure, and extend into the insulating layer(s) 130 to land on the bond pads 128. As the TDVs 146a further extend to the bond pads 128, a height H₁₄₆ₐ of the TDVs 146a may be greater than the height H₁₄₆ of the TDVs 146 as described with reference to FIG. 1A. In regarding manufacturing, the operation S202 including forming the bond pads 128 as described with reference to FIG. 3B has to be performed before an operation for forming of the TDVs 146a (as similar to the operation S210 described with reference to FIG. 3F), such that the TDVs 146a can be landed on the bond pads 128.

Variations may be applied to detailed structure of the TDVs 146a. In some embodiments similar to the embodiments described with reference to FIG. 1B and FIG. 1C, each TDV 146a may include the conductive column 148, and further include the barrier layer 150 and the insulating liner 152 wrapping around the conductive column 148. In other embodiments as similar to the embodiments described with reference to FIG. 4A and FIG. 4B, the substrate 100 is reformed by an insulating material, and each TDV 146a may be formed without an insulating liner at its sidewall.

As will be further illustrated, each of the semiconductor die 10 described with reference to FIG. 1A through FIG. 1C, FIG. 4A and FIG. 4B and the semiconductor die 10a described with reference to FIG. 5 can be further processed to form a semiconductor package.

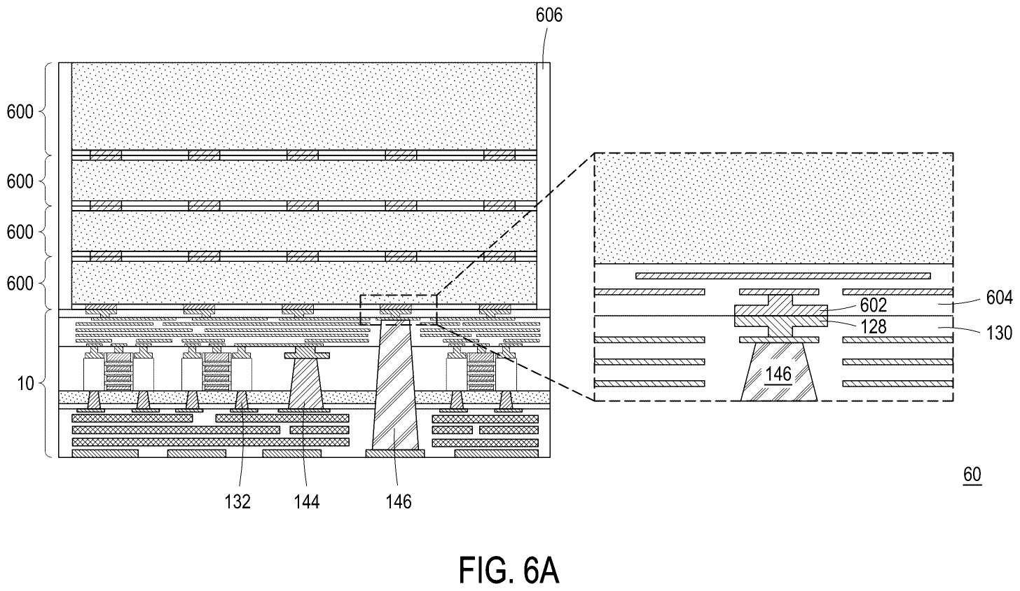

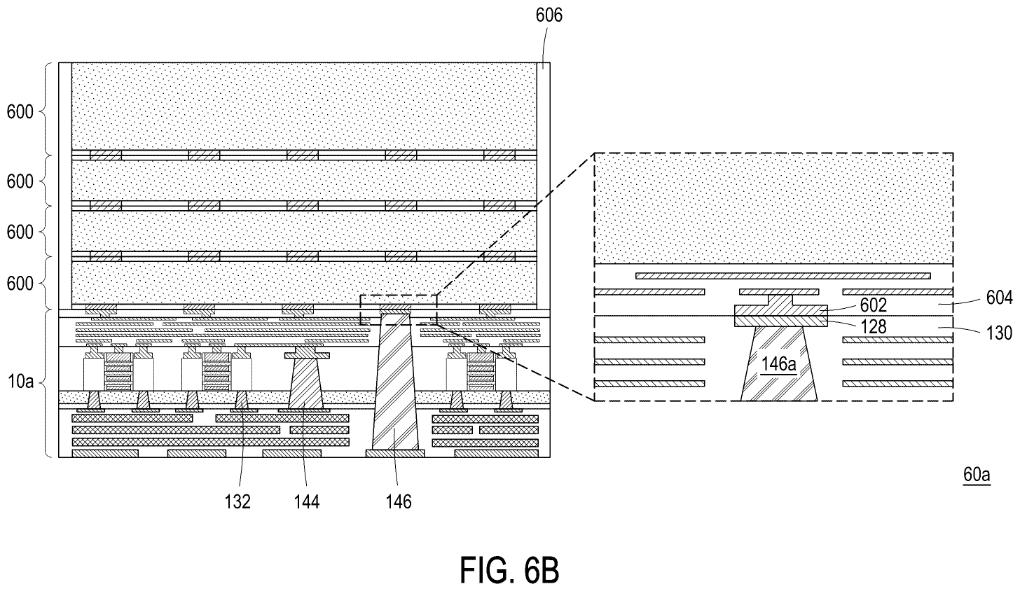

FIG. 6A is a schematic cross-sectional view illustrating a semiconductor package 60 including the semiconductor die 10, according to some embodiments of the present disclosure.

In the semiconductor package 60, multiple device dies 600 are stacked on the semiconductor die 10. As an example, the device dies 600 are dynamic random access memory (DRAM) die, while the semiconductor die 10 is a logic die or a static random access memory (SRAM) die. The device dies 600 are bonded with one another through dielectric-to-dielectric and metal-to-metal bonding. Similarly, a bottommost one of the device dies 600 is bonded to the semiconductor die 10 via dielectric-to-dielectric and metal-to-metal bonding. To be more specific, bond pads 602 arranged along a bottom side of the bottommost device die 600 are directly bonded to the bond pads 128 exposed at the frontside of the semiconductor die 10. In addition, an insulating layer 604 exposed at the bottom side of the device die 600 is directly bonded to the insulating layer 130 exposed at the frontside of the semiconductor die 10. By employing the TDVs 146, signals came from the backside of the semiconductor die 10 can be provided to the frontside of the semiconductor die 10 and input to the device dies 600 with fewest IR loss. In the same way, signals from the device dies 600 can be efficiently transferred to the backside of the semiconductor die 10 through the TDVs 146.

According to some embodiments, during manufacturing, the device dies 600 in chip form are bonded to the semiconductor die 10 in wafer form, and the device dies 600 are laterally encapsulated by a dielectric material 606, such as silicon oxide or the like. A subsequent singulation process may cut through the dielectric material 606, and singulate the semiconductor die 10 from the wafer structure. Consequently, sidewalls of the dielectric material 606 may be substantially coplanar with sidewalls of the semiconductor die 10.

FIG. 6B is a schematic cross-sectional view illustrating a semiconductor package 60a including the semiconductor die 10a, according to some embodiments of the present disclosure. The semiconductor package 60a is nearly identical with the semiconductor package 60 described with reference to FIG. 6A, except that the TDVs 146a in the semiconductor package 60a further extend to the bond pads 128 of the semiconductor die 10a.

In addition to chip-on-wafer (CoW) bonding manner, the semiconductor die 10/10a can be bonded with another package component by using wafer-on-wafer (WoW) bonding manner, according to some other embodiments of the present disclosure.

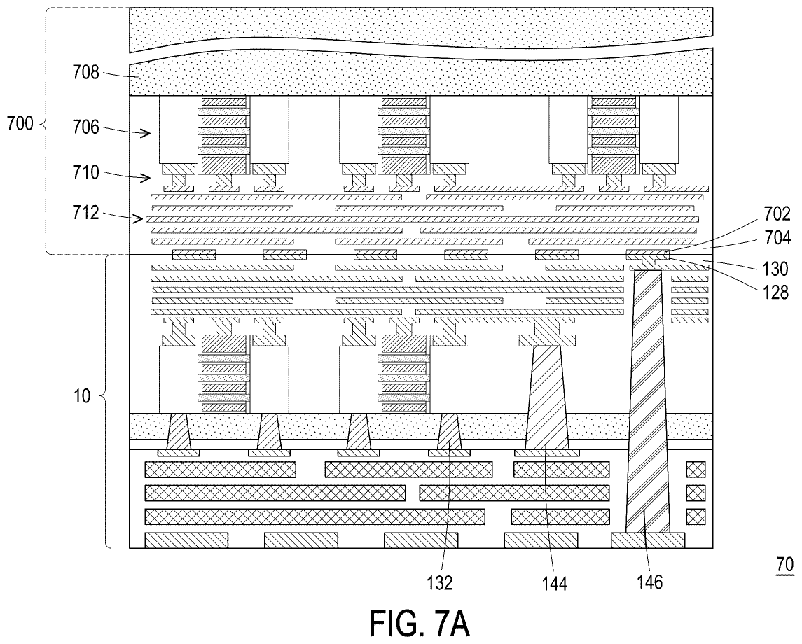

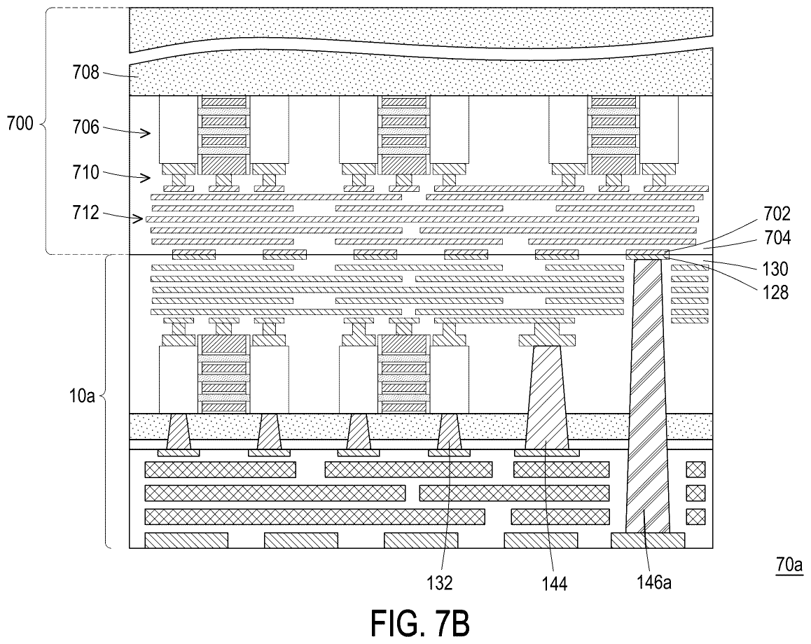

FIG. 7A is a schematic cross-sectional view illustrating a semiconductor package 70 including the semiconductor die 10, according to some embodiments of the present disclosure.

In the semiconductor package 70, a device die 700 is bonded to the semiconductor die 10. Specifically, the device die 700 is in wafer form while being bonded to the semiconductor die 10 also in wafer form. After the wafer-to-wafer bonding, a singulation process may cut through the bonded wafer structures, and the semiconductor die 10 in chip form and the device die 700 in chip form are resulted. As a consequence of this process, sidewalls of the semiconductor 10 may be substantially coplanar with sidewalls of the device die 700.

The device die 700 is bonded to the frontside of the semiconductor die 10 via dielectric-to-dielectric and metal-to-metal bonding. Specifically, bond pads 702 arranged along a bottom side of the device die 700 are directly bonded to the bond pads 128 exposed at the frontside of the semiconductor die 10. In addition, an insulating layer 704 exposed at the bottom side of the device die 700 is bonded to the insulating layer 130 exposed at the frontside of the semiconductor die 10. By employing the TDVs 146, signals came from the backside of the semiconductor die 10 can be provided to the frontside of the semiconductor die 10 and input to the device die 700 with fewest IR loss. In the same way, signals from the device die 700 can be efficiently transferred to the backside of the semiconductor die 10 through the TDVs 146.

As the device die 700 and the semiconductor die 10 may be both implemented by a logic die or a SRAM die, the device die 700 is similar to the semiconductor die 10. Specifically, the device die 700 also includes transistors 706 formed on a front surface of a substrate 708, and has MEOL metallization patterns 710 as well as a frontside BEOL structure 712 formed over the transistors 706. According to some embodiments, the substrate 708 is a carrier substrate, such as a silicon carrier substrate. The transistors 706 may be similar to the transistors 102 described with reference to FIG. 1A. Also, the MEOL metallization patterns 710 may include elements similar to the contact patterns 110 and the contact vias 112, 114 described with reference to FIG. 1A, and the BEOL structure 712 may include elements similar to the dielectric layers 122 and the embedded conductive patterns 124 and conductive vias described with reference to FIG. 1A.

As a difference from the semiconductor die 10, the device die 700 may not include backside structures, and does not require through vias for bridging frontside and backside of the device die 700. Specifically, a back surface of the substrate 708 facing away from the transistors 706 may be exposed, and vias extending through the substrate 708 may be absent. However, in alternative embodiments, the device die 700 may include the backside structures similar to the backside interconnects 134, the backside power rails 138 and the backside pads 140 described with reference to FIG. 1A, and use through vias similar to the backside vias 132, TSVs 144 and TDVs 146 described with reference to FIG. 1A, for bridging frontside and backside of the device die 700.

FIG. 7B is a schematic cross-sectional view illustrating a semiconductor package 70a including the semiconductor die 10a, according to some embodiments of the present disclosure. The semiconductor package 70a is nearly identical with the semiconductor package 70 described with reference to FIG. 7A, except that the TDVs 146a in the semiconductor package 70a further extend to the bond pads 128 of the semiconductor die 10a.

Furthermore, more device dies can be stacked on the device die 700 via chip-on-wafer (CoW) bonding manner.

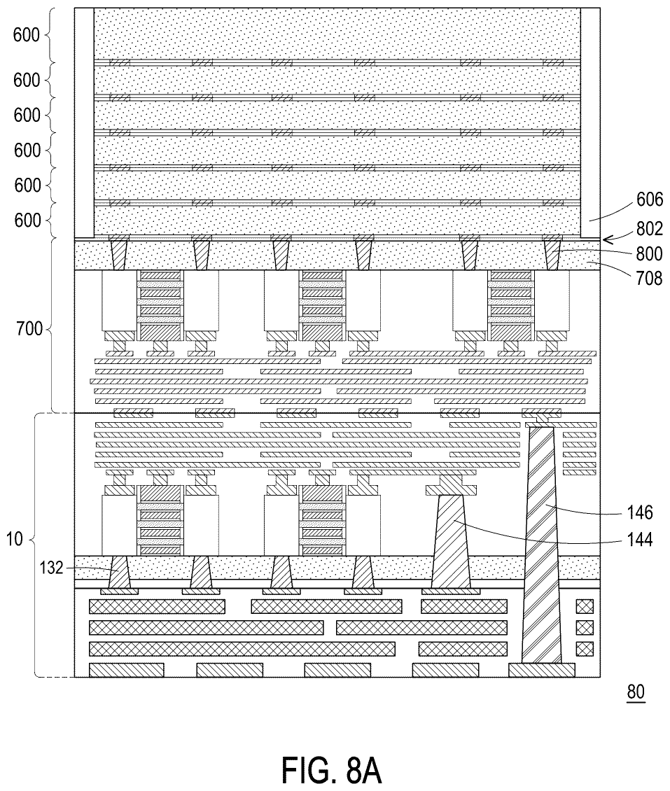

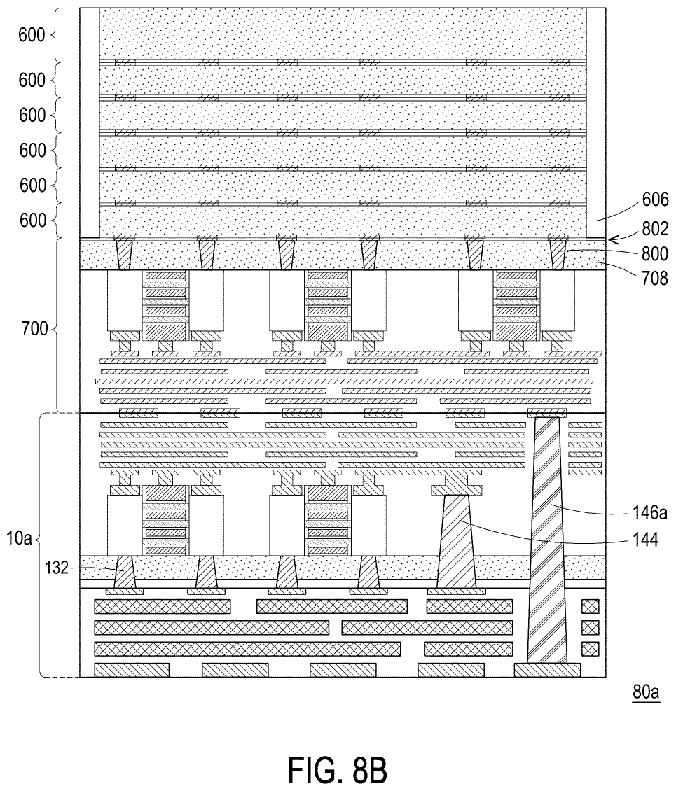

FIG. 8A is a schematic cross-sectional view illustrating a semiconductor package 80 including the semiconductor die 10, according to some embodiments of the present disclosure.

In the semiconductor package 80, the device dies 600 described with reference to FIG. 6A and FIG. 6B are stacked on the device die 700, which is bonded onto the semiconductor die 10. Specifically, after the device die 700 is bonded to the semiconductor die 10 while the device die 700 and the semiconductor die 10 are both in wafer form, the device dies 600 in chip form are bonded onto the device die 700, and are laterally encapsulated by the dielectric material 606. After the chip-to-wafer bonding and the encapsulation, a singulation process may cut through the dielectric material 606 and the bonded wafer structures. Accordingly, the semiconductor die 10 and the device dies 600, 700 all are resulted in chip form. In addition, the sidewalls of the dielectric material 606 may be substantially coplanar with the sidewalls of the device die 700 and the sidewalls of the semiconductor die 10.

In order to establish communication between the device die 700 and the device dies 600 bonded to the backside of the device die 700, backside vias 800 may be formed through the substrate 708 of the device die 700, and at least one routing layer 802 may be formed on a back surface of the substrate 708 of the device die 700. In some embodiment where the bottommost device die 600 is bonded to the device die 700 via dielectric-to-dielectric and metal-to-metal bonding, bond pads exposed at a top surface of the routing layer 802 are directly bonded to the bond pads 602 of the bottommost device die 600 (as shown in FIG. 6A), and an insulating layer exposed at the top surface of the routing layer 802 is directly bonded to the insulating layer 604 of the bottommost device die 600 (also shown in FIG. 6A). Although not shown, according to some embodiments, TSVs and TDVs similar to the TSVs 132 and the TDVs 146 described with reference to FIG. 1A may be formed through the substrate 708 of the device die 100 as well.

FIG. 8B is a schematic cross-sectional view illustrating a semiconductor package 80a including the semiconductor die 10a, according to some embodiments of the present disclosure. The semiconductor package 80a is nearly identical with the semiconductor package 80 described with reference to FIG. 8A, except that the TDVs 146a in the semiconductor package 80a further extend to the bond pads 128 of the semiconductor die 10a.

In further embodiments, multiple device dies may be separately arranged on the semiconductor die 10/10a, rather than being stacked on the semiconductor die 10/10a.

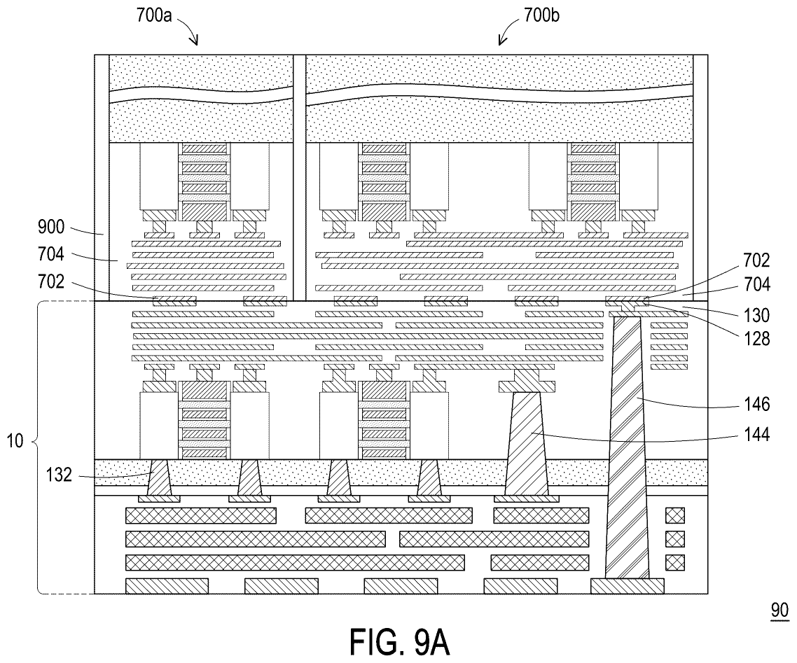

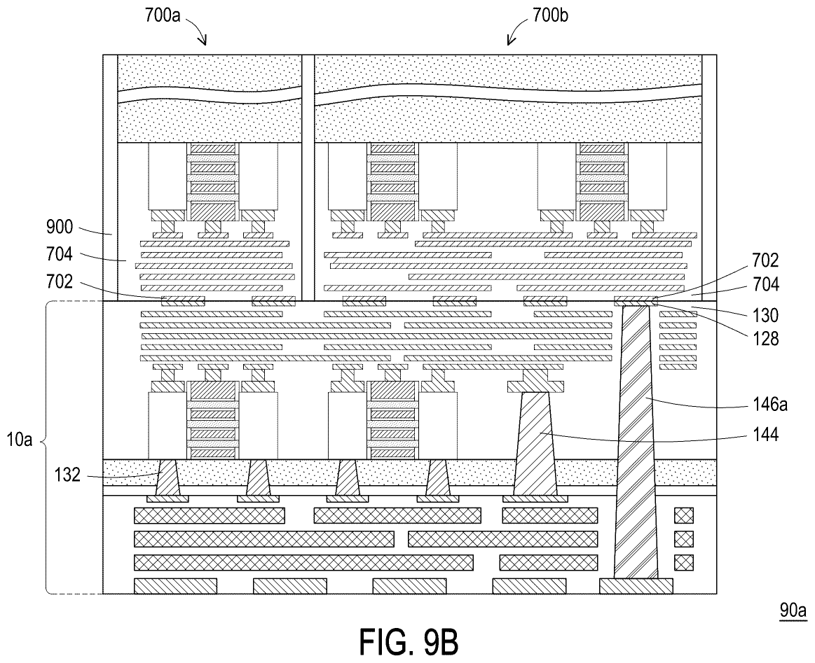

FIG. 9A is a schematic cross-sectional view illustrating a semiconductor package 90 including the semiconductor die 10, according to some embodiments of the present disclosure.

In the semiconductor package 90, device dies 700a, 700b (or more) are arranged at the same height and separately bonded to the frontside of the semiconductor die 10. The device dies 700a, 700b are respectively similar to the device die 700 described with reference to FIG. 7A and FIG. 7B. Detailed structures of the device dies 700a, 700b may be referred to the description about the device die 700 provided with reference to FIG. 7A and FIG. 7B. As a difference from the device die 700, the device dies 700a, 700b are each smaller in size as compared to the device die 700.

According to some embodiments, a frontside of each of the device dies 700a, 700b is bonded to the frontside of the semiconductor die 10 via dielectric-to-dielectric bonding and metal-to-metal bonding. In these embodiments, the bond pads 702 exposed at the frontside of the device die 700a and the bond pads 702 exposed at the frontside of the device die 700b are directly bonded to the bond pads 128 exposed at the frontside of the semiconductor die 10. Also, the insulating layer 704 exposed at the frontside of the device die 700a and the insulating layer 704 exposed at the frontside of the device die 700b are directly bonded to the insulating layer 130 exposed at the frontside of the semiconductor die 10.

During manufacturing, the device dies 700a, 700b in chip form are bonded onto the semiconductor die 10 in wafer form, and a dielectric material 900 is provided on the semiconductor die 10 to laterally encapsulate each of the device dies 700a, 700b. After the chip-to-wafer bonding and the encapsulation, a singulation process may cut through the dielectric material 900 and singulate the semiconductor die 10 from the wafer structure. As a result, sidewalls of the dielectric material 900 may be substantially coplanar with the sidewalls of the semiconductor die 10.

By employing the TDVs 146, signals came from the backside of the semiconductor die 10 can be provided to the frontside of the semiconductor die 10 and input to the device dies 700a, 700b with fewest IR loss. In the same way, signals from the device dies 700a, 700b can be efficiently transferred to the backside of the semiconductor die 10 through the TDVs 146. Although not specifically shown, each of the device dies 700a, 700b may overlap one or more of the TDVs 146. Alternatively, at least one of the device dies 700a, 700b may not overlap any of the TDVs 146.

FIG. 9B is a schematic cross-sectional view illustrating a semiconductor package 90a including the semiconductor die 10a, according to some embodiments of the present disclosure. The semiconductor package 90a is nearly identical with the semiconductor package 90 described with reference to FIG. 9A, except that the TDVs 146a in the semiconductor package 90a further extend to the bond pads 128 of the semiconductor die 10a.

As above, a semiconductor die and a semiconductor package including the semiconductor die are provided. The semiconductor die is formed with active devices accessible from both frontside and backside of the semiconductor die, and includes through device vias (TDVs) bridging the frontside and the backside of the semiconductor die with few IR loss. Specifically, the TDVs continuously extend from backside pads at the backside of the semiconductor die, to top metals as topmost conductive patterns in a frontside BEOL structure of the semiconductor die. Alternatively, the TDVs continuously extend from the backside pads to frontside bond pads at the frontside of the semiconductor die. As compared to a combination of conductive patterns and vias, the TDVs provide interface-less conduction paths, thus communication between the frontside and the backside of the semiconductor die can be provided with much fewer IR loss. When the semiconductor die is bonded with one or more of other device dies in a semiconductor package, the device die(s) attached onto one side of the semiconductor die can be efficiently routed to the other side of the semiconductor die through the TDVs.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In an aspect of the present disclosure, a semiconductor die is provided. The semiconductor die comprises: active devices, formed on a front surface of a substrate; frontside metallization layers, stacked over the active devices; bond pads, laid over the frontside metallization layers, and arranged along a frontside of the semiconductor die; backside metallization layers, formed on a back surface of the substrate; backside pads, formed on the backside metallization layers, and arranged along a backside of the semiconductor die; and through device vias, continuously extending through the backside metallization layers and the substrate from the backside pads, and further extending into the frontside metallization layers.

In another aspect of the present disclosure, a semiconductor package is provided. The semiconductor package comprises: a semiconductor die, bonded with another device die by a frontside. The semiconductor die comprises: active devices, formed on a front surface of a substrate; frontside metallization layers, stacked over the active devices; bond pads, laid over the frontside metallization layers, and arranged along the frontside of the semiconductor die; backside metallization layers, formed on a back surface of the substrate; backside pads, formed on the backside metallization layers, and arranged along a backside of the semiconductor die; and through device vias, continuously extending through the backside metallization layers and the substrate from the backside pads, and further extending into the frontside metallization layers.

In yet another aspect of the present disclosure, a method for manufacturing a semiconductor die is provided. The method comprises: forming active devices on a front surface of a substrate; forming frontside metallization layers over the active devices; laying bond pads over the frontside metallization layers, wherein the bond pads are arranged along a frontside of the semiconductor die; forming backside metallization layers on a back surface of the substrate; forming through device vias penetrating through the backside metallization layers and the substrate, to extend into the frontside metallization layers; and forming backside pads on the backside metallization layers and the through device vias.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor die, comprising:
active devices, formed on a front surface of a substrate;
frontside metallization layers, stacked over the active devices;
bond pads, laid over the frontside metallization layers, and arranged along a frontside of the semiconductor die;
backside metallization layers, formed on a back surface of the substrate;
backside pads, formed on the backside metallization layers, and arranged along a backside of the semiconductor die; and
through device vias, continuously extending through the backside metallization layers and the substrate from the backside pads, and further extending into the frontside metallization layers.

2. The semiconductor die according to claim 1, wherein the through device vias continuously extend from the backside pads to a topmost one of the frontside metallization layers.

3. The semiconductor die according to claim 1, wherein the through device vias continuously extend through the backside metallization layers, the substrate and the frontside metallization layers.

4. The semiconductor die according to claim 1, wherein the through device vias continuously extend to the bond pads from the backside pads.

5. The semiconductor die according to claim 1, further comprising:
backside vias, extending through the substrate to establish electrical connection between the active devices and the backside metallization layers; and
through substrate vias, extending through the substrate to establish electrical connection between the backside metallization layers and the frontside metallization layers, and disposed around the active devices.

6. The semiconductor die according to claim 5, wherein the through device vias are formed with a first height greater than a second height of the backside vias and a third height of the through substrate vias.

7. The semiconductor die according to claim 6, wherein the third height is greater than the second height.

8. The semiconductor die according to claim 1, wherein the through device vias respectively comprise:
a conductive column; and
a barrier layer, wrapping around the conductive column.

9. The semiconductor die according to claim 8, wherein each of the through device vias further comprises an insulating liner wrapping around the barrier layer.

10. A semiconductor package, comprising:
a semiconductor die, bonded with another device die by a frontside, and comprising:
active devices, formed on a front surface of a substrate;
frontside metallization layers, stacked over the active devices;
bond pads, laid over the frontside metallization layers, and arranged along the frontside of the semiconductor die;
backside metallization layers, formed on a back surface of the substrate;
backside pads, formed on the backside metallization layers, and arranged along a backside of the semiconductor die; and
through device vias, continuously extending through the backside metallization layers and the substrate from the backside pads, and further extending into the frontside metallization layers.

11. The semiconductor package according to claim 10, wherein the semiconductor die is bonded with the device die via dielectric-to-dielectric and metal-to-metal bonding.

12. The semiconductor package according to claim 10, further comprising:
additional device dies, stacked on the device die; and
a dielectric material, laterally encapsulating the device die and the additional device dies, wherein sidewalls of the dielectric material are substantially coplanar with sidewalls of the semiconductor die.

13. The semiconductor package according to claim 10, wherein the frontside of the semiconductor die is bonded to a frontside of the device die, and sidewalls of the device die are substantially coplanar with sidewalls of the semiconductor die.

14. The semiconductor package according to claim 13, further comprising:
additional device dies, stacked on the device die; and
a dielectric material, laterally encapsulating the additional device dies, wherein sidewalls of the dielectric material are substantially coplanar with the sidewalls of the device die and the sidewalls of the semiconductor die.

15. The semiconductor package according to claim 10, further comprising:
an additional device die, bonded to the frontside of the semiconductor die, and laterally spaced apart from the device die; and
a dielectric material, laterally encapsulating each of the device die and the additional device die, wherein sidewalls of the dielectric material are substantially coplanar with sidewalls of the semiconductor die.

16. A method for manufacturing a semiconductor die, comprising:
forming active devices on a front surface of a substrate;
forming frontside metallization layers over the active devices;
laying bond pads over the frontside metallization layers, wherein the bond pads are arranged along a frontside of the semiconductor die;
forming backside metallization layers on a back surface of the substrate;
forming through device vias penetrating through the backside metallization layers and the substrate, to extend into the frontside metallization layers; and
forming backside pads on the backside metallization layers and the through device vias.

17. The method according to claim 16, wherein the bond pads are laid before formation of the through device vias.

18. The method according to claim 16, wherein the bond pads are laid after formation of the through device vias.

19. The method according to claim 16, further comprising forming backside vias and through substrate vias before formation of the backside metallization layers, wherein the backside vias are formed through the substrate to reach the active devices, the through substrate vias are formed through the substrate to establish electrical connection with the frontside metallization layers, and are disposed around the active devices.

20. The method according to claim 16, wherein a non-Bosch etching process is involved for forming the through device vias.
